(19) United States
(12) Patent Application Publication
(10) Pub. No.: US 2025/0159963 A1
(43) Pub. Date: May 15, 2025

(54) REDUCED GATE EDGE CAPACITANCE

(71) Applicant: International Business Machines Corporation, Armonk, NY (US)

(72) Inventors: Takashi Ando, Eastchester, NY (US); Reinaldo Vega, Mahopac, NY (US); Nicholas Anthony Lanzillo, Wynantskill, NY (US); David Wolpert, Poughkeepsie, NY (US); James P. Mazza, Saratoga Springs, NY (US)

(21) Appl. No.: 18/508,541

(22) Filed: Nov. 14, 2023

(51) Int. Cl. H01L 29/423; H01L 29/40; H01L 29/66; H01L 29/78

(52) U.S. Cl. CPC H10D 64/518; H10D 30/023; H10D 30/611; H10D 64/01; H10D 64/018

(57) ABSTRACT

A field effect transistor (FET) device is provided. The FET device includes an active region and a gate. The active region includes a source at a first end of the active region and a drain at a second end of the active region. The gate extends across the active region and includes at least one end extending past a corresponding edge of the active region by a sub-lithographic dimension.

### BACKGROUND

The present disclosure generally relates to fabrication methods and resulting structures for semiconductor devices. More specifically, the present disclosure relates to a semiconductor device structure with a reduced gate edge capacitance.

A transistor is a semiconductor device used to amplify or switch electrical signals and power and is one of the basic building blocks of modern electronics. A field-effect transistor (FET) is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a field effect transistor (FET) device is provided. The FET device includes an active region and a gate. The active region includes a source at a first end of the active region and a drain at a second end of the active region. The gate extends across the active region and includes at least one end extending past a corresponding edge of the active region by a sub-lithographic dimension. The FET device therefore provides for a reduction in a gate past active region (PC past RX) of an FET.

According to an aspect of the disclosure, a field effect transistor (FET) device is provided and includes an active region, a gate, a contact and first and second spacers. The active region includes a source at a first end of the active region and a drain at a second end of the active region. The gate extends transversely across the active region and includes first and second opposite ends respectively extending past corresponding edges of the active region by a sub-lithographic dimension. The contact is disposed in contact with the gate within a footprint of the active region. The first and second spacers respectively contact the first and second ends of the gate. The FET device therefore provides for a reduction in a gate past active region (PC past RX) of an FET.

According to an aspect of the disclosure, a field effect transistor (FET) device is provided and includes an active region, a gate, a contact and a spacer. The active region includes a source at a first end of the active region and a drain at a second end of the active region. The gate extends transversely across the active region and includes first and second opposite ends, the first end extending past a first corresponding edge of the active region by a sub-lithographic dimension and the second end extending past a second corresponding edge of the active region in excess of the sub-lithographic dimension. The contact is disposed in contact with the second end of the gate at an exterior of the active region. The spacer contacts the first end of the gate. The FET device therefore provides for a reduction in a gate past active region (PC past RX) of an FET.

According to an aspect of the disclosure, a field effect transistor (FET) device is provided and includes first and second active regions, first and second gates, a contact, first spacers and second spacers. Each of the first and second active regions includes a source at a first end thereof and a drain at a second end thereof. The first and second gates extend transversely across the first and second active regions, respectively. Each of the first and second gates includes complementary first ends extending past first corresponding edges of the first and second active regions by a sub-lithographic dimension and complementary second ends extending past second corresponding edges of the first and second active regions in excess of the sub-lithographic dimension. The contact is disposed in contact with the complementary first ends of the first and second gates and the first and second corresponding edges of the first and second active regions. The first spacers contact the complementary first ends of the first and second gates. The second spacers contact the complementary second ends of the first and second gates. The FET device therefore provides for a reduction in a gate past active region (PC past RX) of an FET.

According to an aspect of the disclosure, a method of assembling a field effect transistor (FET) device is provided. The method includes forming an active region with a gate extending across the active region, opening a trench along an end of the gate, performing cyclic metal oxidation and etching to reform the end of the gate increasingly inwardly toward a corresponding edge of the active region and forming a spacer in the trench at the end of the gate once the end of the gate extends past the corresponding edge of the active region by a sub-lithographic dimension. The method therefore provides for a reduction in a gate past active region (PC past RX) of an FET.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a schematic top-down view of an FET device with reduced gate material (e.g., PC) past an active area/region (e.g., RX) at two edges of an active region in accordance with one or more embodiments of the present disclosure;

FIG. 2 is a schematic top-down view of an FET device with reduced PC past RX at one edge of an active region in accordance with one or more embodiments of the present disclosure;

FIG. 3 is a schematic top-down view of an FET device with reduced PC past RX at two edges of a first and second active regions in accordance with one or more embodiments of the present disclosure;

FIG. 4 is a flow diagram illustrating a method of assembling an FET device in accordance with one or more embodiments of the present disclosure;

FIG. 5 is a schematic top down view of an initial structure of an FET device assembly in accordance with one or more embodiments of the present disclosure;

FIG. 6 is a schematic top down view of a first intermediate structure of an FET device assembly in accordance with one or more embodiments of the present disclosure;

FIG. 7 is a schematic top down view of a second intermediate structure of an FET device assembly in accordance with one or more embodiments of the present disclosure;

FIG. 8 is a schematic top down view of a third intermediate structure of an FET device assembly in accordance with one or more embodiments of the present disclosure; and

FIG. 9 is a schematic top down view of a late stage structure of an FET device assembly in accordance with one or more embodiments of the present disclosure.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a field effect transistor (FET) device is provided. The FET device includes an active region and a gate. The active region includes a source at a first end of the active region and a drain at a second end of the active region. The gate extends across the active region and includes at least one end extending past a corresponding edge of the active region by a sub-lithographic dimension. The FET device therefore provides for a reduction in a gate past active region (PC past RX) of an FET.

In additional or alternative embodiments, the gate includes the at least one end extending past the corresponding edge of the active region by the sub-lithographic dimension and a contact is disposed in contact with a second end of the gate at an exterior of the active region. The FET device therefore provides for a reduction in a gate past active region (PC past RX) of an FET at one side of the active region.

In additional or alternative embodiments, a spacer contacts the one end of the gate. The FET device therefore provides for a reduction in a gate past active region (PC past RX) of an FET at one side of the active region.

In additional or alternative embodiments, the gate includes opposite ends respectively extending past corresponding edges of the active region by the sub-lithographic dimension and a contact is disposed in contact with the gate within a footprint of the active region. The FET device therefore provides for a reduction in a gate past active region (PC past RX) of an FET at opposite sides of the active region.

In additional or alternative embodiments, spacers respectively contact the opposite ends of the gate. The FET device therefore provides for a reduction in a gate past active region (PC past RX) at opposite sides of the active region.

In additional or alternative embodiments, the sub-lithographic dimension is 5 nm or less along a longitudinal axis of the gate. The FET device therefore provides for a complementary-metal-oxide-semiconductor (CMOS) compatible way to achieve a reduction in a gate past active region (PC past RX).

In additional or alternative embodiments, the gate includes a replacement metal gate and the replacement metal gate includes one of tungsten and aluminum. The FET device therefore provides for a complementary-metal-oxide-semiconductor (CMOS) compatible way to achieve a reduction in a gate past active region (PC past RX).

According to an aspect of the disclosure, a field effect transistor (FET) device is provided and includes an active region, a gate, a contact and first and second spacers. The active region includes a source at a first end of the active region and a drain at a second end of the active region. The gate extends transversely across the active region and includes first and second opposite ends respectively extending past corresponding edges of the active region by a sub-lithographic dimension. The contact is disposed in contact with the gate within a footprint of the active region. The first and second spacers respectively contact the first and second ends of the gate. The FET device therefore provides for a reduction in a gate past active region (PC past RX) of an FET.

In additional or alternative embodiments, the sub-lithographic dimension is 5 nm or less along a longitudinal axis of the gate. The FET device therefore provides for a complementary-metal-oxide-semiconductor (CMOS) compatible way to achieve a reduction in a gate past active region (PC past RX).

In additional or alternative embodiments, the gate includes a replacement metal gate and the replacement metal gate includes one of tungsten and aluminum. The FET device therefore provides for a complementary-metal-oxide-semiconductor (CMOS) compatible way to achieve a reduction in a gate past active region (PC past RX).

According to an aspect of the disclosure, a field effect transistor (FET) device is provided and includes an active region, a gate, a contact and a spacer. The active region includes a source at a first end of the active region and a drain at a second end of the active region. The gate extends transversely across the active region and includes first and second opposite ends, the first end extending past a first corresponding edge of the active region by a sub-lithographic dimension and the second end extending past a second corresponding edge of the active region in excess of the sub-lithographic dimension. The contact is disposed in contact with the second end of the gate at an exterior of the active region. The spacer contacts the first end of the gate. The FET device therefore provides for a reduction in a gate past active region (PC past RX) of an FET.

In additional or alternative embodiments, the sub-lithographic dimension is 5 nm or less along a longitudinal axis of the gate. The FET device therefore provides for a complementary-metal-oxide-semiconductor (CMOS) compatible way to achieve a reduction in a gate past active region (PC past RX).

In additional or alternative embodiments, the gate includes a replacement metal gate and the replacement metal gate includes one of tungsten and aluminum. The FET device therefore provides for a complementary-metal-oxide-semiconductor (CMOS) compatible way to achieve a reduction in a gate past active region (PC past RX).

According to an aspect of the disclosure, a field effect transistor (FET) device is provided and includes first and second active regions, first and second gates, a contact, first spacers and second spacers. Each of the first and second active regions includes a source at a first end thereof and a drain at a second end thereof. The first and second gates extend transversely across the first and second active regions, respectively. Each of the first and second gates includes complementary first ends extending past first corresponding edges of the first and second active regions by a sub-lithographic dimension and complementary second ends extending past second corresponding edges of the first and second active regions in excess of the sub-lithographic dimension. The contact is disposed in contact with the complementary first ends of the first and second gates and the first and second corresponding edges of the first and second active regions. The first spacers contact the complementary first ends of the first and second gates. The second spacers contact the complementary second ends of the first and second gates. The FET device therefore provides for a reduction in a gate past active region (PC past RX) of an FET.

In additional or alternative embodiments, the sub-lithographic dimension is 5 nm or less along each longitudinal axis of each of the first and second gates. The FET device therefore provides for a complementary-metal-oxide-semiconductor (CMOS) compatible way to achieve a reduction in a gate past active region (PC past RX).

In additional or alternative embodiments, the first and second gates each include a replacement metal gate and the replacement metal gate includes one of tungsten and aluminum. The FET device therefore provides for a complementary-metal-oxide-semiconductor (CMOS) compatible way to achieve a reduction in a gate past active region (PC past RX).

According to an aspect of the disclosure, a method of assembling a field effect transistor (FET) device is provided. The method includes forming an active region with a gate extending across the active region, opening a trench along an end of the gate, performing cyclic metal oxidation and etching to reform the end of the gate increasingly inwardly toward a corresponding edge of the active region and forming a spacer in the trench at the end of the gate once the end of the gate extends past the corresponding edge of the active region by a sub-lithographic dimension. The method therefore provides for a reduction in a gate past active region (PC past RX) of an FET.

In additional or alternative embodiments, the sub-lithographic dimension is 5 nm or less along a longitudinal axis of the gate. The FET device therefore provides for a complementary-metal-oxide-semiconductor (CMOS) compatible way to achieve a reduction in a gate past active region (PC past RX).

In additional or alternative embodiments, the opening includes opening the trench at one end of the gate, the performing of the cyclic metal oxidation and etching includes reforming the one end of the gate increasingly inwardly toward the corresponding edge of the active region, the forming includes forming the spacer in the trench at the one end of the gate once the one end of the gate extends past the corresponding edge of the active region by the sub-lithographic dimension and the method further includes disposing a contact in contact with the gate at an exterior of the active region. The method therefore provides for a complementary-metal-oxide-semiconductor (CMOS) compatible way to achieve a reduction in a gate past active region (PC past RX).

In additional or alternative embodiments, the opening includes opening trenches at opposite ends of the gate, the performing of the cyclic metal oxidation and etching includes reforming the opposite ends of the gate increasingly inwardly toward corresponding edges of the active region, the forming includes forming spacers at the opposite ends of the gate once the opposite ends of the gate extend past the corresponding edges of the active region by the sub-lithographic dimension and the method further comprises disposing a contact in contact with the gate within a footprint of the active region. The method therefore provides for a complementary-metal-oxide-semiconductor (CMOS) compatible way to achieve a reduction in a gate past active region (PC past RX).

In additional or alternative embodiments, the forming includes forming first and second active regions with first and second gates extending across the first and second active regions, respectively, the opening includes opening trenches at complementary first and second ends of the first and second gates, the performing of the cyclic metal oxidation and etching includes reforming the complementary first ends of the first and second gates increasingly inwardly toward first corresponding edges of the first and second active regions, the forming includes forming spacers at the complementary first ends of the first and second gates once the complementary first ends of the first and second gates extend past the first corresponding edges of the first and second active region by the sub-lithographic dimension and the method further includes disposing a contact in contact with the complementary first ends of the first and second gates and the first corresponding edges of the first and second active regions. The method therefore provides for a complementary-metal-oxide-semiconductor (CMOS) compatible way to achieve a reduction in a gate past active region (PC past RX).

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, an FET includes a source, a drain and a gate whereby a voltage applied to the gate will alter the conductivity between the source and the drain. FETs can be formed and assembled by various processes including lithography, for example. As semiconductor devices continue to become reduced in size, the limits of lithographic processes are becoming increasingly apparent. In particular, when lithography is used to assemble a FET, there is typically an extension of gate material past edges of an active area defined by the source and the drain and the region between the source and the drain. This extension of the gate past the active area (i.e., PC past RX) can be significant and can lead to an edge capacitance that degrades a performance of the FET.

Accordingly, there remains a need for lithographic processes that are complementary-metal-oxide-semiconductor (CMOS) compatible and that provide for a reduction in PC past RX of an FET.

Turning now to an overview of the aspects of the disclosure, one or more embodiments of the disclosure address the above-described shortcomings of the prior art by providing an FET device that includes an active region and a gate. The active region includes a source at a first end of the active region and a drain at a second end of the active region. The gate extends across the active region and includes at least one end extending past a corresponding edge of the active region by a sub-lithographic dimension.

The above-described aspects of the disclosure address the shortcomings of the prior art by providing for a reduction in PC past RX to sub-lithographic dimensions that in turn provides for a reduction in edge capacitance (Cedge) using cyclic metal oxidation and etching. For an FET, a gate edge outside of the RX is exposed by trench opening and cyclic metal oxidation (i.e., plasma oxidation) and etching (i.e., RIE or wet etching, e.g. DHF) is performed. The trench is then refilled with spacer materials (e.g. SiN).

Turning now to a more detailed description of aspects of the present disclosure, FIG. 1 depicts an FET device 101 that includes an active region 110 and a gate 120. The active region 110 includes a source 111 at a first end of the active region 110 and a drain 112 at a second end of the active region 110, which is opposite the first end. The active region 110 further includes a first edge 113, a second edge 114 opposite the first edge 113 and a footprint 115 that is partially delimited by the first edge 113 and the second edge 114. The gate 120 extends transversely across the active region 110 and has a longitudinal axis A1. The gate 120 includes a first end 121 and a second end 122 opposite the first end 121. The first end 121 extends past the first edge 113 by a sub-lithographic dimension D1 and the second end 122 extends past the second edge 114 by the sub-lithographic dimension D1. The gate 120 can be provided as a replacement metal gate and can include one or more of a low resistivity metallic material, such as tungsten and aluminum.

In accordance with embodiments, the sub-lithographic dimension D1 is about 5 nm or less defined along the longitudinal axis A1. Since the first and second ends 121 and 122 extend past the first and second edges 113 and 114, respectively, by only the sub-lithographic dimension D1, edge capacitance of the first and second ends 121 and 122 with the source 111 and the drain 112 of the active region 110 is substantially reduced. A performance factor of the FET device 101 is thereby improved.

As shown in FIG. 1, the FET device 101 further includes a contact 130, a first spacer 141 and a second spacer 142. The contact 130 is disposed in contact with the gate 120 between the first edge 113 and the second edge 114 and thus within the footprint 115 of the active region 110. The first spacer 141 contacts or abuts with the first end 121 of the gate 120 and the second spacer 142 contacts or abuts with the second end 122 of the gate 120.

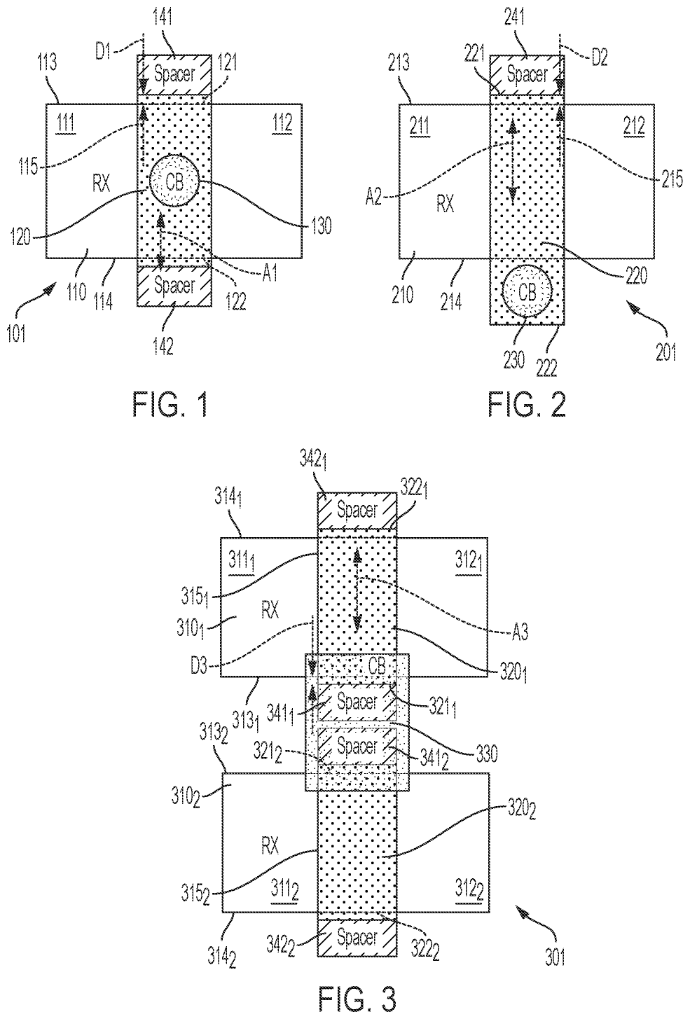

FIG. 2 depicts an FET device 201 that includes an active region 210 and a gate 220. The active region 210 includes a source 211 at a first end of the active region 210 and a drain 212 at a second end of the active region 210, which is opposite the first end. The active region 210 further includes a first edge 213, a second edge 214 opposite the first edge 213 and a footprint 215 that is partially delimited by the first edge 213 and the second edge 214. The gate 220 extends transversely across the active region 210 and has a longitudinal axis A2. The gate 220 includes a first end 221 and a second end 222 opposite the first end 221. The first end 221 extends past the first edge 213 by a sub-lithographic dimension D2 and the second end 222 extends past the second edge 214 by a distance that exceeds the sub-lithographic dimension D2. The gate 220 can be provided as a replacement metal gate and can include one or more of a low resistivity metallic material, such as tungsten and aluminum.

In accordance with embodiments, the sub-lithographic dimension D2 is about 5 nm or less defined along the longitudinal axis A2. Since the first end 221 extends past the first edge 213 by only the sub-lithographic dimension D2, edge capacitance of the first end 221 with the source 211 and the drain 212 of the active region 210 is substantially reduced. A performance factor of the FET device 201 is thereby improved.

As shown in FIG. 2, the FET device 201 further includes a contact 230 and a spacer 241. The contact 230 is disposed in contact with the second end 222 of the gate 220 between the second edge 214 and a distal end of the second end 222 and at an exterior of the footprint 215 of the active region 210. The spacer 241 contacts or abuts with the first end 221 of the gate 220.

FIG. 3 depicts an FET device 301 that includes first and second active regions 310₁ and 310₂ and first and second gates 320₁ and 320₂. The first active region 310₁ includes a source 3111 at a first end of the first active region 310₁ and a drain 312₁ at a second end of the first active region 310₁, which is opposite the first end. The first active region 310₁ further includes a first edge 313₁, a second edge 314₁ opposite the first edge 313₁ and a footprint 315₁ that is partially delimited by the first edge 313₁ and the second edge 314₁. The second active region 310₂ includes a source 311₂ at a first end of the second active region 310₂ and a drain 312₂ at a second end of the second active region 310₂, which is opposite the first end. The second active region 310₂ further includes a first edge 313₂, a second edge 314₂ opposite the first edge 313₂ and a footprint 315₂ that is partially delimited by the first edge 313₂ and the second edge 314₂. The first gate 320₁ extends transversely across the first active region 310₁ and has a longitudinal axis A3. The first gate 320₁ includes a first end 321₁ and a second end 322₁ opposite the first end 321₁. The first end 321₁ extends past the first edge 313₁ by a sub-lithographic dimension D3 and the second end 322₁ extends past the second edge 314₁ by the sub-lithographic dimension D3. The first gate 320₁ can be provided as a replacement metal gate and can include one or more of a low resistivity metallic material, such as tungsten and aluminum. The second gate 320₂ extends transversely across the second active region 310₂ and has a longitudinal axis A3. The second gate 320₂ includes a first end 321₂ and a second end 322₂ opposite the first end 321₂. The first end 321₂ extends past the first edge 313₂ by the sub-lithographic dimension D3 and the second end 322₂ extends past the second edge 314₂ by the sub-lithographic dimension D3. The second gate 320₂ can be provided as a replacement metal gate and can include one or more of a low resistivity metallic material, such as tungsten and aluminum.

In accordance with embodiments, the sub-lithographic dimension D3 is about 5 nm or less defined along the longitudinal axis A3. Since the first ends 321₁ and 321₂ extend past the first edges 313₁ and 313₂ by only the sub-lithographic dimension D3, edge capacitances of the first ends 321₁ and 321₂ with the sources 311₁ and 311₂ and the drains 312₁ and 312₂ of the first and second active regions 310₁ and 310₂ are substantially reduced. Also, since the second ends 322₁ and 322₂ extend past the second edges 314₁ and 314₂ by only the sub-lithographic dimension D3, edge capacitances of the second ends 322₁ and 322₂ with the sources 311₁ and 311₂ and the drains 312₁ and 312₂ of the first and second active regions 310₁ and 310₂ are substantially reduced. A performance factor of the FET device 301 is thereby improved.

As shown in FIG. 3, the FET device 301 further includes a contact 330, first spacers 341₁ and 341₂ and second spacers 342₁ and 342₂. The contact 330 is disposed in contact with the complementary first ends 321₁ and 321₂ of the first and second gates 320₁ and 320₂ and the corresponding first edges 313₁ and 313₂ of the first and second active regions 310₁ and 310₂. The first spacers 341₁ and 341₂ contact the complementary first ends 321₁ and 321₂ of the first and second gates 320₁ and 320₂. The second spacers 342₁ and 342₂ contact the complementary second ends 322₁ and 322₂ of the first and second gates 320₁ and 320₂.

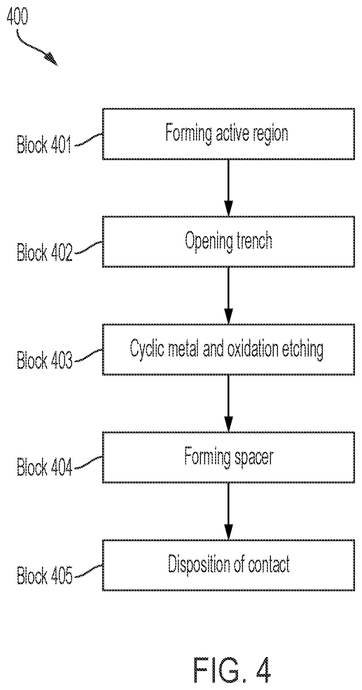

With reference to FIG. 4, a method 400 of assembling an FET device is provided. The method 400 includes forming an active region with a gate extending across the active region (block 401), opening a trench along an end of the gate (block 402), performing cyclic metal oxidation and etching to reform the end of the gate increasingly inwardly toward a corresponding edge of the active region (block 403) and forming a spacer in the trench at the end of the gate once the end of the gate extends past the corresponding edge of the active region by a sub-lithographic dimension of about 5 nm or less along a longitudinal axis of the gate (block 404). The method 400 can further include disposition of a contact (block 405).

In accordance with one or more embodiments of the present disclosure and as shown in FIG. 1, the opening of block 402 can include opening trenches at opposite ends of the gate, the performing of the cyclic metal oxidation and etching of block 403 can include reforming the opposite ends of the gate increasingly inwardly toward corresponding edges of the active region and the forming of block 404 can include forming spacers at the opposite ends of the gate once the opposite ends of the gate extend past the corresponding edges of the active region by the sub-lithographic dimension. In these or other cases, the disposition of the contact of block 405 can include disposing a contact in contact with the gate within a footprint of the active region.

In accordance with one or more embodiments of the present disclosure and as shown in FIG. 2, the opening of block 402 can include opening the trench at one end of the gate, the performing of the cyclic metal oxidation and etching of block 403 can include reforming the one end of the gate increasingly inwardly toward the corresponding edge of the active region and the forming of block 404 can include forming the spacer in the trench at the one end of the gate once the one end of the gate extends past the corresponding edge of the active region by the sub-lithographic dimension. In these or other cases, the disposition of the contact of block 405 can include disposing a contact in contact with the gate at an exterior of the active region.

In accordance with one or more embodiments of the present disclosure and as shown in FIG. 3, the forming of block 401 can include forming first and second active regions with first and second gates extending across the first and second active regions, respectively, the opening of block 402 can include opening trenches at complementary first and second ends of the first and second gates, the performing of the cyclic metal oxidation and etching of block 403 can include reforming the complementary first ends of the first and second gates increasingly inwardly toward first corresponding edges of the first and second active regions and the forming of block 404 can include forming spacers at the complementary first ends of the first and second gates once the complementary first ends of the first and second gates extend past the first corresponding edges of the first and second active region by the sub-lithographic dimension. In these or other cases, the disposition of the contact of block 405 can include disposing a contact in contact with the complementary first ends of the first and second gates and the first corresponding edges of the first and second active regions.

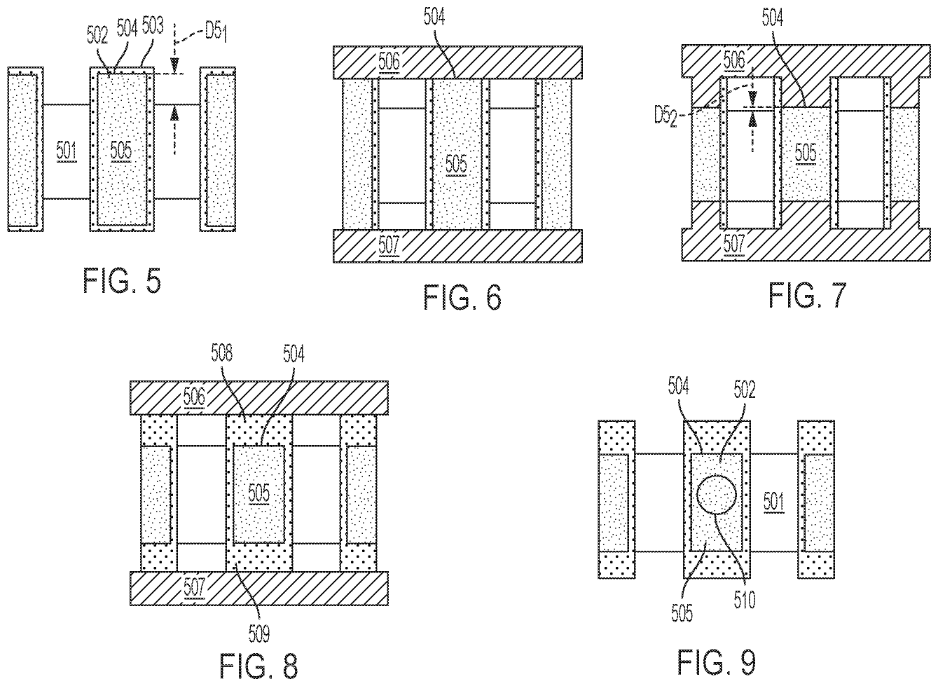

With reference to FIGS. 5-9, the method 400 of FIG. 4 will now be described further. It is to be understood that FIGS. 5-9 generally relate to the embodiments of FIG. 1. This is being done for purposes of clarity and brevity and should not be interpreted as limiting a scope of the description or the following claims in any way. Indeed, it will be readily apparent to any person of ordinary skill that the method 400 of FIG. 4 and the graphics of FIGS. 5-9 apply to the various embodiments of FIGS. 2 and 3 without any undue experimentation.

As shown in FIG. 5, an active region 501 is formed with a gate 502 extending transversely across the active region 501 by a process of record (POR). The gate 502 can be provided as multiple gates and can be provided as a replacement metal gate and can be formed of a low resistivity metallic material, such as one or more of tungsten and aluminum. A spacer 503 is provided to line the gate 502. At this point, the ends 504 and 505 of the gate 502 extend past the corresponding edges of the active region 501 by a distance D51 that exceeds the sub-lithographic dimension (i.e., 5 nm or less).

As shown in FIG. 6, trenches 506 and 507 are cut along the ends 504 and 505 of the gate 502 to expose the ends 504 and 505. Subsequently, as shown in FIG. 7, cyclic metal oxidation and etching are performed or executed via the trenches 506 and 507 to reform the ends 504 and 505 increasingly inwardly toward the corresponding edges of the active region 501. This cyclic metal oxidation and etching can be repeated iteratively until the ends 504 and 505 extend past the corresponding edges of the active region 501 by the sub-lithographic dimension D5₂ (i.e., 5 nm or less along the longitudinal axis of the gate 502).

As shown in FIGS. 8 and 9, spacers 508 and 509 are formed in the trenches 506 and 507 and at the ends 504 and 505 of the gate 502 once the ends 504 and 505 extend past the corresponding edges of the active region 501 by the sub-lithographic dimension D5₂ (see FIG. 7). Interlayer dielectric (ILD) is then used to fill in the remainders of the trenches 506 and 507 and chemical mechanical polishing (CMP) is performed to planarize the ILD. At this point, a contact 510 can be formed in contact with the gate 502 and within the footprint of the active region 501.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A field effect transistor (FET) device, comprising:
an active region comprising a source at a first end of the active region and a drain at a second end of the active region; and
a gate extending across the active region and comprising at least one end extending past a corresponding edge of the active region by a sub-lithographic dimension.

2. The FET device according to claim 1, wherein:
the gate comprises the at least one end extending past the corresponding edge of the active region by the sub-lithographic dimension, and
a contact is disposed in contact with a second end of the gate at an exterior of the active region.

3. The FET device according to claim 2, further comprising a spacer contacting the one end of the gate.

4. The FET device according to claim 1, wherein:
the gate comprises opposite ends respectively extending past corresponding edges of the active region by the sub-lithographic dimension, and
a contact is disposed in contact with the gate within a footprint of the active region.

5. The FET device according to claim 4, further comprising spacers respectively contacting the opposite ends of the gate.

6. The FET device according to claim 1, wherein the sub-lithographic dimension is 5 nm or less along a longitudinal axis of the gate.

7. The FET device according to claim 1, wherein the gate comprises a replacement metal gate.

8. The FET device according to claim 7, wherein the replacement metal gate comprises one of tungsten and aluminum.

9. A field effect transistor (FET) device, comprising:
an active region comprising a source at a first end of the active region and a drain at a second end of the active region;
a gate extending transversely across the active region and comprising first and second opposite ends respectively extending past corresponding edges of the active region by a sub-lithographic dimension;
a contact disposed in contact with the gate within a footprint of the active region; and
first and second spacers respectively contacting the first and second ends of the gate.

10. The FET device according to claim 9, wherein the sub-lithographic dimension is 5 nm or less along a longitudinal axis of the gate.

11. The FET device according to claim 9, wherein the gate comprises a replacement metal gate.

12. The FET device according to claim 11, wherein the replacement metal gate comprises one of tungsten and aluminum.

13. A field effect transistor (FET) device, comprising:
an active region comprising a source at a first end of the active region and a drain at a second end of the active region;
a gate extending transversely across the active region and comprising first and second opposite ends, the first end extending past a first corresponding edge of the active region by a sub-lithographic dimension and the second end extending past a second corresponding edge of the active region in excess of the sub-lithographic dimension;
a contact disposed in contact with the second end of the gate at an exterior of the active region; and
a spacer contacting the first end of the gate.

14. The FET device according to claim 13, wherein the sub-lithographic dimension is 5 nm or less along a longitudinal axis of the gate.

15. The FET device according to claim 13, wherein the gate comprises a replacement metal gate.

16. The FET device according to claim 15, wherein the replacement metal gate comprises one of tungsten and aluminum.

17. A field effect transistor (FET) device, comprising:
first and second active regions, each comprising a source at a first end thereof and a drain at a second end thereof; and
first and second gates extending transversely across the first and second active regions, respectively, each of the first and second gates comprising complementary first ends extending past first corresponding edges of the first and second active regions by a sub-lithographic dimension and complementary second ends extending past second corresponding edges of the first and second active regions in excess of the sub-lithographic dimension;
a contact disposed in contact with the complementary first ends of the first and second gates and the first and second corresponding edges of the first and second active regions;
first spacers contacting the complementary first ends of the first and second gates; and
second spacers contacting the complementary second ends of the first and second gates.

18. The FET device according to claim 17, wherein the sub-lithographic dimension is 5 nm or less along each longitudinal axis of each of the first and second gates.

19. The FET device according to claim 17, wherein the first and second gates each comprise a replacement metal gate.

20. The FET device according to claim 19, wherein the replacement metal gate comprises one of tungsten and aluminum.

21. A method of assembling a field effect transistor (FET) device, the method comprising:
forming an active region with a gate extending across the active region;
opening a trench along an end of the gate;
performing cyclic metal oxidation and etching to reform the end of the gate increasingly inwardly toward a corresponding edge of the active region; and
forming a spacer in the trench at the end of the gate once the end of the gate extends past the corresponding edge of the active region by a sub-lithographic dimension.

22. The method according to claim 21, wherein the sub-lithographic dimension is 5 nm or less along a longitudinal axis of the gate.

23. The method according to claim 21, wherein:
the opening comprises opening the trench at one end of the gate,
the performing of the cyclic metal oxidation and etching comprises reforming the one end of the gate increasingly inwardly toward the corresponding edge of the active region,
the forming comprises forming the spacer in the trench at the one end of the gate once the one end of the gate extends past the corresponding edge of the active region by the sub-lithographic dimension, and
the method further comprises disposing a contact in contact with the gate at an exterior of the active region.

24. The method according to claim 21, wherein:
the opening comprises opening trenches at opposite ends of the gate,
the performing of the cyclic metal oxidation and etching comprises reforming the opposite ends of the gate increasingly inwardly toward corresponding edges of the active region,
the forming comprises forming spacers at the opposite ends of the gate once the opposite ends of the gate extend past the corresponding edges of the active region by the sub-lithographic dimension, and
the method further comprises disposing a contact in contact with the gate within a footprint of the active region.

25. The method according to claim 21, wherein:
the forming comprises forming first and second active regions with first and second gates extending across the first and second active regions, respectively,
the opening comprises opening trenches at complementary first and second ends of the first and second gates,
the performing of the cyclic metal oxidation and etching comprises reforming the complementary first ends of the first and second gates increasingly inwardly toward first corresponding edges of the first and second active regions,
the forming comprises forming spacers at the complementary first ends of the first and second gates once the complementary first ends of the first and second gates extend past the first corresponding edges of the first and second active region by the sub-lithographic dimension, and
the method further comprises disposing a contact in contact with the complementary first ends of the first and second gates and the first corresponding edges of the first and second active regions.
